(19) United States
(12) Patent Application Publication
(10) Pub. No.: US 2025/0167031 A1
(43) Pub. Date: May 22, 2025

(54) CARRIER SUBSTRATE AND MANUFACTURING METHOD OF SEMICONDUCTOR PACKAGE USING SAME

(71) Applicant: Samsung Electronics Co., Ltd., Suwon-si (KR)

(72) Inventors: Hosin SONG, Suwon-si (KR); Yeongkwon KO, Suwon-si (KR); Jiyoung PARK, Suwon-si (KR); Junyeong HEO, Suwon-si (KR)

(73) Assignee: Samsung Electronics Co., Ltd., Suwon-si (KR)

(21) Appl. No.: 18/890,154

(22) Filed: Sep. 19, 2024

(30) Foreign Application Priority Data
Nov. 16, 2023 (KR) 10-2023-0159080
Mar. 11, 2024 (KR) 10-2024-0033846

(51) Int. Cl. H01L 21/683; H01L 21/304; H01L 21/66; H01L 21/68

(52) U.S. Cl. CPC H01L 21/6835; H01L 21/681; H01L 22/12; H01L 21/304; H01L 2221/68309

(57) ABSTRACT

A carrier substrate according to some example embodiments is a carrier substrate having a circular disk shape, and includes a first surface, a second surface opposite surface to first surface, and an inclined surface that extends along the edge of the first surface, has an inclination angle from the first surface, and is configured to reflect incident light from the second surface.

### CROSS-REFERENCE TO RELATED APPLICATION

This application claims priority to and the benefit of Korean Patent Application No. 10-2023-0159080 filed in the Korean Intellectual Property Office on Nov. 16, 2023, and Korean Patent Application No. 10-2024-0033846 filed in the Korean Intellectual Property Office on Mar. 11, 2024, the entire contents of which are incorporated herein by reference.

### BACKGROUND

### 1. Field

Inventive concepts relate to a carrier substrate and methods of manufacturing a semiconductor package using the same.

### 2. Description of the Related Art

Among semiconductor manufacturing processes, many processes may be performed on wafers, and the alignment of wafers is critical, important, and/or desired for such processes to be precisely performed. Notches may be formed at the edges of wafers so as to become references for aligning the wafers. In order to identify positions of notches of wafers, equipment including, for example, light sources and photosensors may be used.

In order to support wafers in semiconductor manufacturing processes, carrier substrates may be bonded to wafers and then be used, and, for example, the positions of the carrier substrates (for example, the positions of notches of glass carriers) may be identified to align the wafers.

In products, such as, for example, high bandwidth memories (HBMs), 2.5D packages, and the like, which are being developed recently, glass carriers may be used as carrier substrates; however, since glass carriers transmit light, it may be difficult to identify the positions of notches of glass carriers with conventional equipment.

### SUMMARY

The present inventive concepts attempt to provide a carrier substrate from which one or more reference positions may be easily detected.

A carrier substrate according to some example embodiments may be a carrier substrate having a circular disk shape, and including a first surface, a second surface opposite to the first surface, and an inclined surface that extends along an edge of the first surface, has an inclination angle from the first surface, and is configured to reflect incident light from the second surface.

A carrier substrate according to some example embodiments is a carrier substrate which has a circular disk shape and is transparent, and includes a first surface, a second surface opposite to the first surface, an inclined surface that extends along an edge of the first surface, and has an inclination angle from the first surface, and is inclined toward the second surface, and a side surface that extends from an edge of the inclined surface to an edge of the second surface, and the inclination angle satisfies the following expression.

$$arcsin ( {n}_{a} / {n}_{s} ) \leq a < 90 ° \qquad [ Expression ]$$

In the expression, a, nₐ, and nₛ are the inclination angle in degrees, the refractive index of air, and the refractive index of the carrier substrate, respectively.

A method of manufacturing a semiconductor package according to some example embodiments embodiment includes preparing a carrier substrate having a circular disk shape including an inclined surface extending along an edge, and defining a notch groove having the shape of a cut formed at the edge, bonding a wafer structure onto the carrier substrate, aligning the carrier substrate, processing the wafer structure, and debonding the carrier substrate, and in the aligning of the carrier substrate, a position of the notch groove is detected by radiating light onto the inclined surface such that light incident on the inclined surface is reflected thereby.

According to some example embodiments embodiment, a carrier substrate has a structure which reflects incident light. Therefore, even in the case of carrier substrates that transmit light, it is possible to easily detect the reference positions of the carrier substrates, using light-receptive sensors.

### BRIEF DESCRIPTION OF THE DRAWINGS

FIG. 1 is a perspective view of a carrier substrate according to some example embodiments.

FIG. 2 is a plan view of the carrier substrate and an enlarged view of a portion of the carrier substrate according to some example embodiments.

FIG. 3 is a cross-sectional view taken along the direction A-A of FIG. 2.

FIG. 4 is a cross-sectional view taken along the direction B-B of FIG. 2.

FIG. 5 is a view for explaining total reflection in the carrier substrate according to some example embodiments.

FIG. 6 is a view illustrating detecting the position of a substrate by a position detection apparatus.

FIGS. 7 to 9 are views for explaining a process of detecting the position of the carrier substrate according to some example embodiments.

FIGS. 10 to 15 are views illustrating a process of manufacturing a semiconductor package using the carrier substrate according to some example embodiments.

### DETAILED DESCRIPTION

In the following detailed description, only certain example embodiments have been shown and described, simply by way of illustration. As those ordinarily skilled in the art would understand, the described example embodiments may be modified in various different ways, all without departing from the spirit or scope of the present inventive concepts.

The drawings and description are to be regarded as illustrative in nature and not restrictive or limiting. Like reference numerals designate like elements throughout the specification.

In addition, the size and thickness of each configuration and/or feature shown in the drawings are arbitrarily shown for understanding and ease of description, but the present inventive concepts are not limited thereto.

Throughout this specification, when a feature is referred to as being “connected” to another features, it may be directly connected to the other part, or may be connected to the other part indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, when the phrase “on a plane” is used, it refers to when a target part is viewed from above (for example, viewed in plan view), and when “on a cross-section” is used, it refers to when the cross-section obtained by cutting a target part vertically is viewed from the side (for example, viewed in cross-section).

Hereinafter, a carrier substrate according to some example embodiments will be described with reference to the drawings. A carrier substrate is a structure that is bonded to a wafer that is thinned by grinding during a process of manufacturing a semiconductor or a semiconductor package, so as to enable additional processes to be performed on the wafer. The carrier substrate may have, for example, a flat or substantially flat plate shape such that the carrier substrate can be bonded to one surface of the wafer. For example, the carrier substrate may have a shape similar to that of the wafer, but example embodiments are not limited thereto. After processes on the wafer are performed, the carrier substrate may be debonded from the wafer. By bonding the carrier substrate to one surface of the wafer, it is possible to perform subsequent processes on the other surface of the wafer without or with reduced warpage of the wafer and/or damage to the wafer.

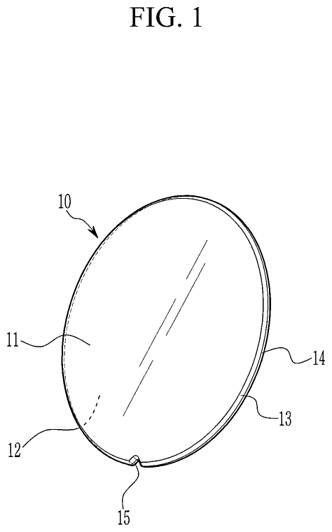

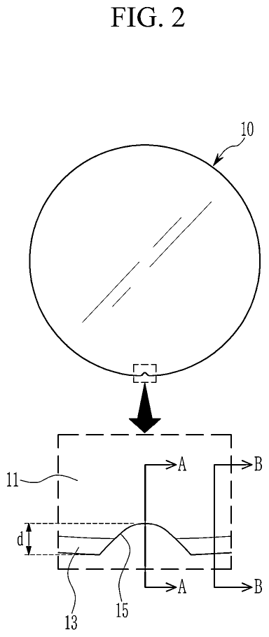

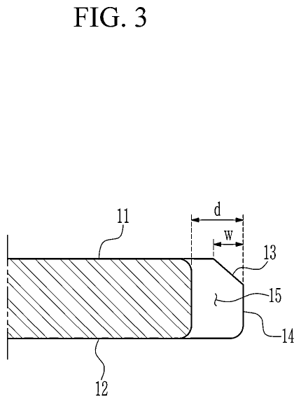

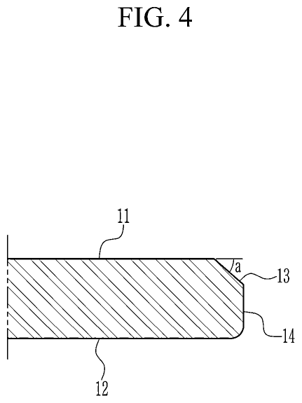

FIG. 1 is a perspective view of a carrier substrate according to some example embodiments, and FIG. 2 is a plan view of the carrier substrate and an enlarged view of a portion of the carrier substrate according to some example embodiments. FIG. 3 is a cross-sectional view taken along the direction A-A of FIG. 2, and FIG. 4 is a cross-sectional view taken along the direction B-B of FIG. 2.

A carrier substrate 10 according to some example embodiments may be a structure which is bonded to one surface of a wafer (not shown in the drawing) so as to support the wafer. The carrier substrate 10 according to some example embodiments may be bonded to one surface of a thin wafer such that it is possible to easily perform processes on the wafer, and may be debonded from the wafer after processing on the wafer is performed.

Referring to FIGS. 1 to 4, the carrier substrate 10 according to some example embodiments may have, for example, a circular disk shape, but example embodiments are not limited thereto. The carrier substrate 10 may include a first surface 11, and a second surface 12 that is opposite to the first surface 11. The first surface 11 and the second surface 12 may be, for example, flat or substantially flat and be parallel or substantially parallel with each other. In the following description, the direction extending from the first surface 11 toward the second surface 12 (or the direction from the second surface toward the first surface) will be defined as the thickness direction. The thickness direction of the carrier substrate 10 may be, for example, a direction perpendicular to the first surface 11 or the second surface 12, but example embodiments are not limited thereto.

Referring to FIGS. 3 and 4, the carrier substrate 10 according to some example embodiments may include an inclined surface 13. The inclined surface 13 may extend along the edge of the first surface 11. For example, according to some example embodiments, the inclined surface 13 may have a shape continuously extending over the entire edge of the first surface 11 along the circumferential direction (except for the area of a notch groove to be described below). The inclined surface 13 may have, for example, a ring shape on a plane, but example embodiments are not limited thereto.

Referring to FIG. 4, the inclined surface 13 may have an inclination angle a from (for example, with) the first surface 11. The inclined surface 13 may be inclined from the first surface 11 toward the second surface 12 by the inclination angle a. According to some example embodiments, the inclination angle a of the inclined surface 13 may be an angle at which light traveling from the second surface 12 toward the first surface 11 can be reflected from (for example, by) the inclined surface 13 without passing through the inclined surface. This will be described below.

The carrier substrate 10 according to some example embodiments may further include a side surface 14 extending from an edge of the above-described inclined surface 13 to the edge of the second surface 12. The side surface 14 may be positioned between the inclined surface 13 and the second surface 12. The side surface 14 may be connected to the inclined surface 13 and to the second surface 12. One edge of the inclined surface 13 may be connected to or directly connected to (for example, contiguous with an edge of) the first surface 11 and the other edge may be connected to or directly connected to (for example, contiguous with an edge of) the side surface 14.

The carrier substrate 10 according to some example embodiments may be transparent. The carrier substrate 10 may, for example, consist of or include a transparent or substantially transparent material, and may contain a glass material. As an example, the carrier substrate 10 may be a glass substrate, but example embodiments are not limited thereto.

For example, during a semiconductor package manufacturing process, after the carrier substrate 10 is bonded to a wafer and various processes are performed on the wafer, the carrier substrate 10 may be debonded from the wafer. When the carrier substrate 10 is debonded from the wafer, stress may be applied to the wafer and the wafer may be deformed and/or damaged. To prevent or reduce the magnitude and/or occurrence of such deformation and/or damage, a method of irradiating a bonding member between the wafer and the carrier substrate 10 with, for example, laser light (for example, a laser wafer supporting system (LWSS)) may be used to debond the carrier substrate 10 from the wafer. In such a case, for example, when the carrier substrate 10 is transparent or substantially transparent and is able to transmit the laser light, the laser light may be radiated onto the carrier substrate 10, whereby it may be possible to easily (for example, relatively easily) debond the carrier substrate 10 from the wafer.

The light transmittance of the carrier substrate 10 may be, for example, smaller than 100%. According to some example embodiments, for example, the light transmittance of the carrier substrate 10 may be equal to, about equal to, or larger than 95%, but example embodiments are not limited thereto.

The carrier substrate 10 may include a reference position for orientation perception and position alignment. For example, the carrier substrate 10 may have one or more marks indicating the reference position. Referring to FIGS. 1 and 2, the carrier substrate 10 according to some example embodiments may include a notch groove 15 as (for example, serving or functioning as) the above-mentioned reference position mark. The notch groove 15 is a structure for marking (for example, indicating) the reference position, and it may be possible to perceive the position and/or orientation of the carrier substrate 10 on the basis of the notch groove 15 (for example, on the basis of the position and/or orientation of the notch groove).

According to some example embodiments, the notch groove 15 may have a shape of a cut formed at (for example, defined or at least partially defined by) a portion of the edge portion of the carrier substrate 10. The notch groove 15 may have the shape of a cut formed (for example, defined or at least partially defined) inwardly from the side surface 14 of the carrier substrate 10. For example, the depth d (see FIG. 3) of the notch groove 15, e.g., an inward depth of a cut in (for example, defined by) the side surface 14 of the carrier substrate, 10 may be about 1 mm, but example embodiments are not limited thereto. Also, the notch groove 15 may have a shape penetrating (for example, extending or defined to extend) from the first surface 11 of the carrier substrate 10 to the second surface 12. The notch groove 15 may have a shape penetrating (for example, extending or defined to extend through) the carrier substrate 10 in the thickness direction. For example, on a plane, the notch groove 15 may have a shape in which the width of a cut decreases inwardly (for example, when moving inwards) from the edge of the carrier substrate 10. On a plane, the notch groove 15 may have the shape of a cut the same as, substantially the same as, or similar to a U or V shape, but example embodiments are not limited thereto.

As described above, the notch groove 15 may have the shape of a cut formed at (for example, defined or at least partially defined by) the edge of the carrier substrate 10, and may have a shape penetrating (for example, extending) from the first surface 11 to the second surface 12 (in the thickness direction). Accordingly, when the carrier substrate 10 is irradiated with light moving towards the first surface 11 or with light moving towards the second surface 12 (for example, in the thickness direction), light may intactly pass through the notch groove 15 without passing through any other medium (the carrier substrate)

This feature may be used to perceive the notch groove, which will be further described below.

According to some example embodiments, on a plane, the notch groove 15 may be defined to have a shape that extends further inwards than the inclined surface 13. For example, an end of the notch groove 15 (for example, the end on the inner side of the carrier substrate) may be positioned further on the inner side (for example, closer to a center) of the carrier substrate 10 relative to an edge of the inclined surface 13 (the edge on the inner side of the carrier substrate). Referring to FIGS. 2 and 3, the depth d of the notch groove 15 may be greater than the width w of the inclined surface 13 on a plane.

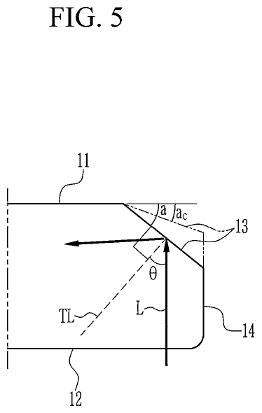

The above-described inclination angle a will be further described in detail. FIG. 5 is a view for explaining total reflection in the carrier substrate according to some example embodiments.

Referring to FIGS. 4 and 5, the inclination angle a refers to an angle that is defined between an imaginary plane obtained by extending the first surface 11 toward the edge of the carrier substrate 10 (or the side surface 14) and the inclined surface 13.

According to some example embodiments, the inclination angle a may have an angle range in which light entering the carrier substrate in the thickness direction from (for example, via) the second surface 12 (for example, incident light in a direction perpendicular to the first surface or the second surface) cannot pass through the inclined surface 13 and may be reflected as it travels to (for example, encounters or is incident upon) the inclined surface 13.

According to some example embodiments, the inclination angle a may satisfy the following expression.

$$arcsin ( {n}_{a} / {n}_{s} ) \leq a < 90 ° \qquad [ Expression ]$$

In the above expression, a, nₐ, and nₛ are the inclination angle (in degrees), the refractive index of air, and the refractive index of the carrier substrate, respectively.

In the above expression, “arcsin (nₐ/nₛ)” represents a threshold angle a_{c} at which light begins to be all reflected without passing through the carrier substrate as it travels from the carrier substrate into the air (i.e., total reflection begins). Accordingly, the inclination angle a may be an angle equal to or larger than the threshold angle a_{c} and smaller than 90°.

Referring to FIG. 5, the inclination angle a is the same as the incidence angle θ of light L entering the carrier substrate toward the inclined surface 13. In other words, the angle θ which the light L entering the carrier substrate toward the inclined surface 13 forms with the tangent line TL to the inclined surface 13 is the same as the inclination angle a (θ=a). Therefore, when the inclination angle a is equal to or larger than the threshold angle a_{c} of the light L entering the carrier substrate toward the inclined surface 13, the light L may not pass through the carrier substrate and may be all reflected.

According to some example embodiments, the carrier substrate 10 may consist of a transparent material. Accordingly, when light is radiated onto the carrier substrate in the thickness direction of the carrier substrate 10 from a position apart from the first surface 11 or second surface 12 of the carrier substrate 10, the light may pass through the carrier substrate 10.

According to some example embodiments, when light is radiated onto the carrier substrate 10 in the thickness direction (for example, when light is radiated onto the carrier substrate from or via the second surface toward the first surface), the light traveling from the second surface 12 toward the first surface 11 may pass through the carrier substrate 10, for example through the first surface 11 in the thickness direction. However, since there is the inclined surface 13 at the edge portion of the first surface 11 of the carrier substrate 10, light incident on the inclined surface 13 cannot pass through the carrier substrate. The light traveling from the second surface 12 toward the inclined surface 13 is reflected (for example, totally, almost totally, or substantially totally reflected), so it cannot pass through the carrier substrate. Accordingly, when light is radiated in the thickness direction of the carrier substrate 10 from a light source apart from one surface of the transparent carrier substrate 10, the light may be perceived on the opposite side to the light source (with the carrier substrate interposed therebetween), but at the edge portion where the inclined surface 13 is positioned, the light may not be perceived or a very small amount of light may be perceived.

Meanwhile, at the edge of the carrier substrate 10, the notch groove 15 is provided. According to some example embodiments, since the notch groove 15 has a shape penetrating (for example, extending through the carrier substrate 10 in the thickness direction and is disposed at the edge portion of the carrier substrate, the notch groove may be positioned so as to overlap a portion of the area where the inclined surface 13 is positioned. Light traveling from the second surface 12 toward the inclined surface 13 may be intactly transmitted at the notch groove 15. Accordingly, by sensing the amount of transmitted light along the edge portion of the carrier substrate 10, it is possible to detect the position of the notch groove 15 at the periphery of the carrier substrate 10.

Hereinafter, a method of detecting the position of the notch groove 15 in the carrier substrate 10 will be described.

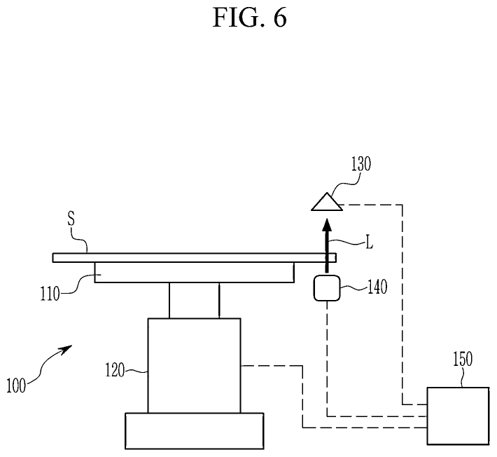

FIG. 6 is a view illustrating the detection of the position of a substrate by a position detection apparatus.

As described above, in a substrate S, a mark indicating a reference position for orientation perception and/or position alignment may be provided, and for example, in the substrate S, the above-mentioned notch groove may be provided (for example, defined) as a mark indicating the reference position. In FIG. 6, a position detection apparatus 100 for detecting the position of the notch groove in the substrate S is shown. Hereinafter, a method of detecting the position of the notch groove in the substrate S by the position detection apparatus 100 will be described with reference to FIG. 6.

Referring to FIG. 6, the position detection apparatus 100 may include, for example, a support unit 110, a light source 140, a photosensor 130, a driver 120, and a controller 150, but example embodiments are not limited thereto. In FIG. 6, the position detection apparatus 100 is schematically shown.

The support unit 110 may support the substrate S. The substrate S to be subjected to position detection may be placed on the support unit 110. The support unit 110 may include a means for fixing the substrate S, such as an electrostatic chuck or a vacuum chuck, and may further include, for example, additional fixing means such as, for example, clamps, but example embodiments are not limited thereto. The support unit 110 may have a plate or plate-like shape that is flat or substantially flat, and one surface of the substrate S may be positioned on the support unit 110. For example, the support unit 110 may have a plate shape extending in the horizontal direction, and the substrate S on the support unit 110 may be aligned (for example, correspondingly aligned) in the horizontal direction. According to some example embodiments, the support unit 110 may have, for example, a disk or disk-like shape that is circular or substantially circular and may have a diameter smaller than that of the substrate S, but example embodiments are not limited thereto. Referring to FIG. 6, the edge portion of the substrate S may or may not be supported on and/or by the support unit 110.

The driver 120 may rotate the support unit 110. The driver 120 may include, for example, a motor, a rotary shaft, and/or a power transmission means for rotation, but example embodiments are not limited thereto. The driver 120 may rotate the support unit 110 to rotate the substrate S that is fixed to the support unit 110. The substrate S may be rotated on an axis passing through the centers of both (for example, opposing) surfaces of the substrate S by the driver 120. For example, the substrate S aligned in the horizontal direction may be rotated on an axis in the vertical direction. The substrate S may be rotated at least one revolution (turn) by the driver 120.

The light source 140 may be disposed apart from the substrate S. The light source 140 may radiate light L onto one surface of the substrate S from a position spaced a predetermined or, alternatively, a desired distance from one surface of the substrate S. The light source 140 may be disposed adjacent to the edge portion of the substrate S. Referring to FIG. 6, the light source 140 may be positioned beneath the substrate S and aligned in the horizontal direction. The light source 140 may be disposed adjacent to the edge portion of the substrate S, and radiate light L toward the edge portion of one surface (for example, the lower surface) of the substrate S. The light L radiated from the light source 140 may pass through the notch groove disposed (for example, defined) at the edge portion of the substrate S.

The light source 140 may include, for example, a known light emitting means such as a light emitting diode (LED), but example embodiments are not limited thereto. The light L which the light source 140 radiates may be visible light. For example, the light L may have a wavelength equal to or larger than 380 nm and equal to or smaller than 780 nm; however, it is not limited thereto and may have a wavelength in various ranges. The light source 140 may be connected to the controller 150 to be described below.

The photosensor 130 may sense the light radiated from the light source 140. For example, the photosensor 130 may sense an amount of light irradiated from the light source 140. The photosensor 130 may be connected to the controller 150 to be described below, and the controller 150 may sense the amount of light received by the photosensor 130, in, for example, real time. The photosensor 130 may be disposed so as to face the above-described light source 140 with the substrate S interposed therebetween. Referring to FIG. 6, the photosensor 130 may be disposed above the substrate S, and may be disposed so as to be spaced a predetermined or, alternatively, a desired distance from the upper surface of the substrate S and be adjacent to the edge portion of the substrate S.

The controller 150 may be connected to the driver 120, the light source 140, and/or the photosensor 130 described above. The controller 150 may transmit a control signal to the driver 120 to control the driver 120 to rotate the support unit 110. The controller 150 may control light radiation of the light source 140. For example, the controller 150 may control the light source 140 to radiate light while the support unit 110 rotates. The controller 150 may sense the amount of light received by the photosensor 130, in real time, while the substrate S rotates and while the light is radiated from the light source 140. According to some example embodiments, the controller 150 may detect the position of the notch groove in the substrate S by comparing the amounts of light that are sensed in real time by the photosensor 130. Hereinafter, the method of detecting the position of the notch groove 15 in the carrier substrate 10 according to some example embodiments will be described in more detail.

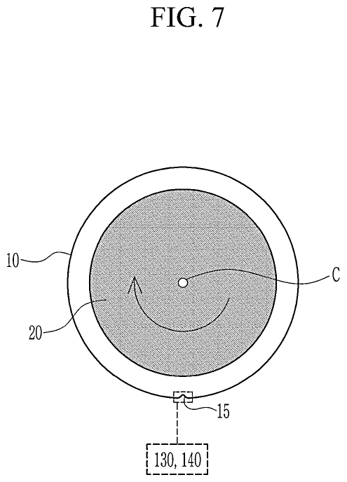

FIGS. 7 to 9 are views for explaining a process of detecting the position of the carrier substrate according to some example embodiments. A description of FIGS. 7 to 9 describes a method of detecting the position of the notch groove of the carrier substrate by the position detection apparatus 100 shown in FIG. 6.

Referring to FIGS. 7 to 9, a wafer structure 20 may be bonded to the first surface 11 of the carrier substrate 10 according to some example embodiments, the notch groove 15 may be provided at (for example defined or at least partially defined by) an edge portion of the carrier substrate. The carrier substrate 10 may, for example, have a circular disk shape, and may consist of a transparent or substantially transparent material that transmits light.

The wafer structure 20 may have a circular disk shape, and may have a diameter smaller than that of the carrier substrate 10. The wafer structure 20 may be disposed concentrically with the carrier substrate 10. The wafer structure 20 may include a wafer substrate. The wafer structure 20 may further include, for example, electronic devices (for example, semiconductor chips) disposed on the wafer substrate. The wafer structure 20 may further include one or more molding materials encapsulating or at least partially encapsulating the electronic devices on the wafer substrate. The wafer structure 20 may have a structure in which a plurality of layers are stacked.

The wafer structure 20 may be positioned at a center portion of the carrier substrate 10. On a plane, the wafer structure 20 may be positioned further inwards than the inclined surface 13 so as not to overlap (for example completely overlap) with the inclined surface 13 of the carrier substrate 10, e.g., such that the inclined surface 13 of the carrier substrate 10 is exposed or at least partially exposed.

Between the carrier substrate 10 and the wafer structure 20, a bonding member 50 may be disposed. By the bonding member 50, the wafer structure 20 may be bonded onto the carrier substrate 10. The bonding member 50 may contain, for example, an epoxy resin and/or other bonding materials, but example embodiments are not limited thereto. The bonding member 50 may have, for example, a property in which the shape thereof may be fluidly changed by heat or pressure, but example embodiments are not limited thereto.

Alternatively, or additionally, the bonding member 50 may have a property in which the adhesive force is changed by laser light.

The method of detecting the position of the notch groove 15 of the carrier substrate 10 according to some example embodiments will be described. First, the carrier substrate 10 is rotated. Referring to FIG. 7, the carrier substrate 10 may be rotated on a central axis C. Referring to FIG. 6, the carrier substrate 10 may be fixed onto the support unit 110 of the position detection apparatus 100, and be rotated one or more revolutions by the rotation of the support unit 110.

Subsequently, while the carrier substrate 10 rotates, light is radiated onto the carrier substrate 10, and the light passing through the edge portion of the carrier substrate 10 is sensed. Referring to FIGS. 6, 8, and 9 together, the light source 140 disposed apart from the second surface 12 of the carrier substrate 10 radiates light L toward the inclined surface 13 perpendicularly to (for example, through or via) the second surface 12. At this time, the photosensor 130 disposed apart from the first surface 11 so as to face the light source 140 senses light L passing through the carrier substrate 10 and the notch groove.

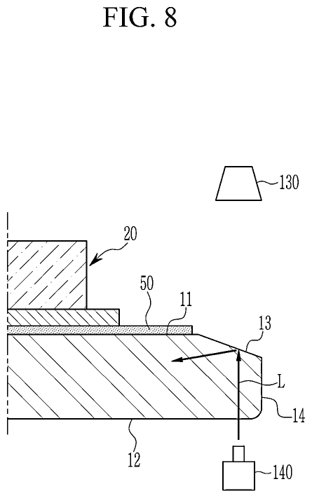

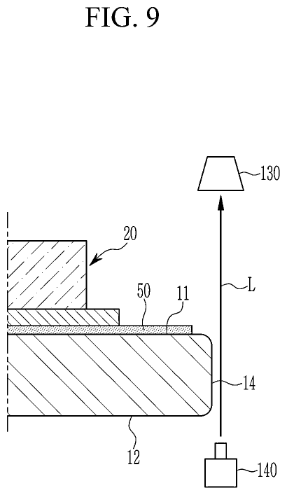

In the carrier substrate 10 according to some example embodiments, the light L radiated (for example, transmitted) from the second surface (12) side toward the inclined surface 13 is reflected (for example, almost totally or substantially totally” from (for example, by) the inclined surface 13. Accordingly, the light L cannot pass through the inclined surface 13. Therefore, on the first surface (11) side, the light may not be sensed or a very small amount of light may be sensed (see FIG. 8). However, while the carrier substrate 10 rotates, the notch groove (reference symbol “15”) (see, for example, FIG. 7) may, for at least a time, be positioned at (for example, aligned with) the position(s) where the light source 140 and the photosensor 130 are disposed. At such time(s), since the light L radiated from the light source 140 intactly passes through the notch groove 15, the light L may be sensed by the photosensor 130 (see FIG. 9). Accordingly, while the carrier substrate 10 rotates, the amount of light that is sensed by the photosensor 130 becomes maximum when the notch groove 15 is positioned (for example, aligned) between the light source and the photosensor. Therefore, it is possible to detect the position of the notch groove 15.

The process of detecting the position of the notch groove 15 of the carrier substrate 10 will be described in more detail. First of all, a reference value setting process may be included. When light L is radiated from the second surface (12) side of the carrier substrate 10 (the light source) toward the first surface (11) side (the photosensor), the maximum value of the amount of light that passes through the carrier substrate 10 and is sensed by the photosensor (hereinafter, referred to as the amount of transmitted light) may be set as a reference value. Since the transmittance of the transparent carrier substrate 10 may be smaller than 100%, the reference value may be differently set depending on properties of the carrier substrate 10.

Thereafter, while the carrier substrate 10 is rotated, light L is radiated from the light source 140, disposed adjacent to the edge portion of the second surface 12 of the carrier substrate 10, toward the inclined surface 13. At this time, the amount of light passing through the carrier substrate 10 may be sensed by the photosensor 130 disposed adjacent to the edge portion of the first surface 11 of the carrier substrate 10 so as to face the light source. The light L traveling from the second surface 12 toward the inclined surface 13 cannot pass through the inclined surface 13 and is reflected from an inner surface thereof; however, it intactly (for example, without reflecting) or substantially intactly passes through the notch groove 15 without passing through any other medium (for example, the first and/or second surfaces of the carrier substrate). Accordingly, when the photosensor 130 senses the amount of light passing through the inclined surface 13, it may sense an amount of light smaller than the amount of transmitted light, and when the photosensor 130 senses the amount of light passing through the notch groove 15, it may sense an amount of light larger than the amount of transmitted light. For example, among the positions at the periphery (for example, edge portion) of the carrier substrate 10, a position from which a value larger than the reference value is sensed by the photosensor 130 may be perceived or understood as the position of the notch groove 15.

The position of the notch groove 15 of the carrier substrate 10 detected through the above-described method may be, for example, a reference position for aligning the carrier substrate 10 in a semiconductor package manufacturing process. Accordingly, the position of the notch groove 15 may become a reference position for processing the wafer structure bonded to the carrier substrate 10.

Hereinafter, a method of manufacturing a semiconductor package using the carrier substrate 10 according to some example embodiments described above will be described.

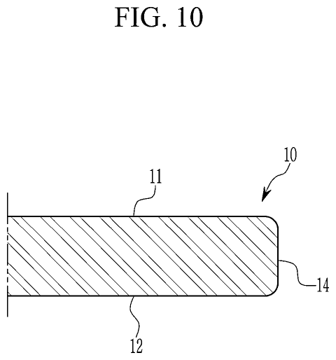

FIGS. 10 to 15 are views illustrating a process of manufacturing a semiconductor package using the carrier substrate according to some example embodiments. The method of manufacturing a semiconductor package according to some example embodiments includes a step of preparing a carrier substrate, a step of bonding a wafer structure onto the carrier substrate, a step of aligning the carrier substrate, a step of processing the wafer structure, and a step of debonding the carrier substrate. Hereinafter, the individual steps will be described in detail.

First, the carrier substrate 10 is prepared. The carrier substrate 10 according to some example embodiments may have a circular disk or similar shape, but example embodiments are not limited thereto. Referring to FIG. 10, the carrier substrate 10 may include the first surface 11 and the second surface 12 which are flat or substantially flat and are parallel or substantially parallel to each other, and the side surface 14 connecting the first surface 11 and the second surface 12. Each of the connection portion between (for example, of or connecting) the first surface 11 and the side surface 14 and the connection portion between (for example, of or connecting) the second surface 12 and the side surface 14 may be, for example, chamfered, but example embodiments are not limited thereto.

The carrier substrate 10 according to some example embodiments may be transparent or substantially transparent, and the notch groove 15 may be formed in (for example, defined to have) the shape of a cut at a portion of an edge portion of the carrier substrate 10. The notch groove 15 is formed in (for example, defined to have) a shape penetrating (for example, extending) from the first surface 11 to the second surface 12.

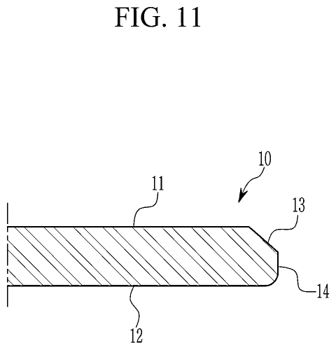

Referring to FIG. 11, in the step of preparing the carrier substrate 10, the edge of the first surface 11 of the carrier substrate 10 is processed to form the inclined surface 13. The inclined surface 13 may extend along (for example, around and/or contiguously with) the edge of the first surface and have a ring shape or ring-like shape (for example, a ring or ring-like shape cut off or interrupted by the notch groove) on a plane. The inclined surface 13 may be formed by, for example, a cutting means such as a laser, but example embodiments are not limited thereto. Also, the inclined surface may be processed by a polishing means. The inclined surface 13 may connect the first surface 11 and the side surface 14.

According to some example embodiments, the inclined surface 13 may have an inclination angle (reference symbol “a”) (see FIG. 4) from (for example, with) the first surface 11 toward the second surface 12. The inclination angle a may satisfy the following expression:

$$arcsin ( {n}_{a} / {n}_{s} ) \leq a < 90 ° \qquad [ Expression ]$$

In the expression, a, nₐ, and nₛ are the inclination angle in degrees, the refractive index of air, and the refractive index of the carrier substrate, respectively.

In the above expression, “arcsin (nₐ/nₛ)” represents the threshold angle a_{c} at which light begins to be reflected (for example, totally, almost totally, or substantially totally reflected) as it travels from the carrier substrate into the air. Accordingly, the inclination angle a may be an angle equal to or larger than the threshold angle a_{c} and smaller than 90°.

As an example, the carrier substrate may be a glass substrate, but example embodiments are not limited thereto. In such a case, it is assumed that the refractive index of the carrier substrate is 1.52 and the refractive index of air is 1.0003. In such a case, the inclination angle a may have an angle range equal to or larger than 41.14° and smaller than 90°, or approximately so. However, such is an example, and as the refractive index varies depending on the material of the carrier substrate 10, the inclination angle a may accordingly vary depending on the material of the carrier substrate 10.

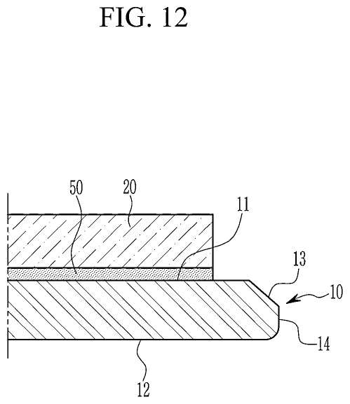

Referring to FIG. 12, the wafer structure 20 is bonded onto the carrier substrate 10 with the formed inclined surface 13. The wafer structure 20 may be bonded to the first surface 11 of the carrier substrate 10 by interposing the bonding member 50 between the wafer structure 20 and the carrier substrate 10. For example, the wafer substrate may be bonded to the carrier substrate 10.

The wafer structure 20 may have, for example, a circular disk shape, and may have a diameter smaller than that of the carrier substrate 10, but example embodiments are not limited thereto. The wafer structure 20 may be, for example, disposed concentrically with the carrier substrate 10. The wafer structure 20 may be bonded to an inner area of the first surface 11 of the carrier substrate 10 such that at least a portion of the first surface 11 and/or of the inclined surface 13 of the carrier substrate 10 are exposed. For example, after the wafer substrate is bonded to the carrier substrate 10, the wafer substrate may be ground so as to be thinned, and on the thinned wafer substrate, wiring structures may be formed and electronic devices may be disposed, whereby the wafer structure 20 may be manufactured. Further, the electronic devices and the wiring structures may be encapsulated or at least partially encapsulated on the wafer substrate, using one or more molding materials.

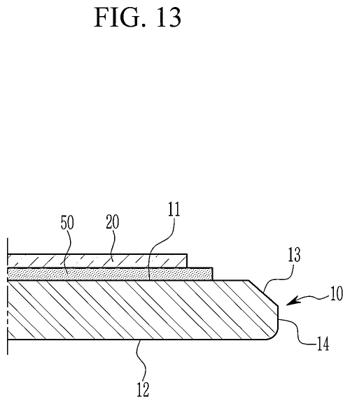

Referring to FIG. 13, after the wafer structure 20 is bonded to the carrier substrate 10, the wafer structure 20 may be ground. The surface (hereinafter, referred to as the back surface) of the wafer structure 20 that is opposite to the surface bonded to the carrier substrate 10 may be ground. For example, after the wafer structure 20 is formed by disposing the electronic devices on the wafer substrate and encapsulating them with the molding material, the wafer structure 20 may be processed by grinding the molding material. Since the wafer structure 20 is bonded to the carrier substrate 10, it is possible to reduce or prevent, for example, warpage of the thin wafer structure 20. Subsequently, the carrier substrate 10 with the wafer structure 20 bonded thereto may be aligned. According to some example embodiments, for alignment of the carrier substrate 10, the position of the notch groove 15 may be detected by radiating light L onto the inclined surface 13 of the carrier substrate 10 so as to be reflected (for example totally, almost totally, or substantially totally reflected.

The position of the notch groove 15 of the carrier substrate 10 may be detected using the position detection apparatus 100 as shown in, for example, FIG. 6. While the carrier substrate 10 is rotated, the light L may be radiated from the light source 140 disposed apart from the second surface 12 of the carrier substrate 10 toward the inclined surface 13 perpendicularly (for example, in a direction perpendicular to) to the second surface 12, and the light may be sensed by the photosensor 130 disposed apart from the first surface 11 so as to face the light source 140 with the carrier substrate 10 interposed therebetween. The light L radiated from the light source 140 is incident on the inclined surface 13 may be reflected (for example, totally, almost totally, or substantially totally reflected) therefrom (for example, thereby), but may intactly or substantially intactly pass through the notch groove 15. Accordingly, by analyzing the amounts of light sensed by the photosensor 130, it is possible to detect the position of the notch groove 15 of the carrier substrate 10.

As described above, when the light is radiated onto the edge portion of the carrier substrate 10 with the inclined surface 13 formed while the carrier substrate 10 is rotated, the amount of light passing through the carrier substrate 10 may be sensed to detect the position of the notch groove 15. Referring to FIG. 8, the light L radiated from the second surface (12) side toward the inclined surface 13 is reflected (for example, totally, almost totally, or substantially totally reflected) from the inclined surface 13. Accordingly, only a very small amount of light may be sensed on the first surface (11) side. Referring to FIG. 9, as the carrier substrate 10 rotates, the notch groove 15 may be or become positioned at the position where (for example, aligned with) the light source 140 and the photosensor 130 are disposed. At this time, since the light L radiated from the light source 140 intactly or substantially intactly passes through the notch groove 15, a maximum amount of light may be sensed by the photosensor 130.

Therefore, by analyzing the amounts of light that are sensed by the photosensor 130, it is possible to detect the position of the notch groove 15.

According to some example embodiments, when the maximum value of the amount of light radiated from the light source 140 and passing through the carrier substrate 10 the light L is set as the reference value, the position in the carrier substrate 10 when (for example, at which) an amount of light larger than the reference value is sensed by the photosensor 130 may be detected as the position of the notch groove.

The information on the position of the notch groove 15 of the carrier substrate 10 detected through the above-described process may be used to align the carrier substrate 10. The carrier substrate 10 may be, for example, transferred to separate equipment and be aligned. After the carrier substrate 10 is aligned, the wafer structure 20 is processed. In other words, a preceding accurate position alignment step may be beneficial for precise processing on (for example, of) the wafer structure 20.

In the step of processing the wafer structure 20, the edge portion of the wafer structure 20 may be trimmed. Through such an operation, the reference position of the wafer structure 20 may be formed before processing on the wafer structure 20. Additionally or alternatively, by trimming the edge portion of the wafer structure 20, it is possible to prevent the edge portion of the wafer structure 20 from being damaged in the process of processing the wafer structure 20.

The step of processing the wafer structure 20 may include, for example, a process of processing the back surface of the wafer structure 20. The process of processing the back surface of the wafer structure 20 may include, for example, widely known semiconductor processes such as, for example, photolithography, metal thin film formation, plating, etc., but example embodiments are not limited thereto. In the step of processing the wafer structure 20, on the back surface of the wafer structure 20, bumps which may be or include external connection terminals may be formed.

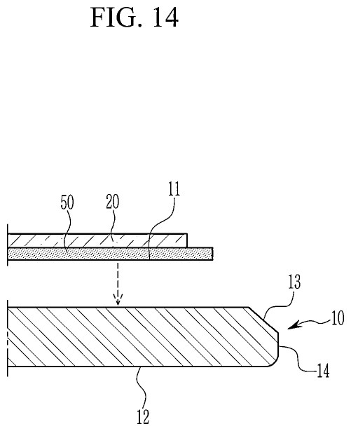

Referring to FIG. 14, after the wafer structure 20 is processed, the carrier substrate 10 is debonded from the wafer structure 20. In the debonding step, the carrier substrate 10 may be separated from the wafer structure 20. Also, in the debonding step, the residue of the bonding member 50 remaining on the wafer structure 20 may be removed by cleaning.

The carrier substrate 10 may be debonded from the wafer structure 20 in various ways depending on, for example, the properties of the bonding member 50. As an example, the bonding member 50 may be heated to debond the carrier substrate 10 from the wafer structure 20. As another example, the bonding member 50 may be alternatively or additionally chemically dissolved to debond the carrier substrate 10 from the wafer structure 20. As a further example, the bonding member 50 may be alternatively or additionally irradiated with laser light to debond the carrier substrate 10 from the wafer structure 20. In such a case, the laser light may be irradiated onto the bonding member 50 through the transparent carrier substrate 10. Accordingly, it may be possible to debond the carrier substrate 10 from the wafer structure 20 more easily as compared to the other (for example, conventional) ways.

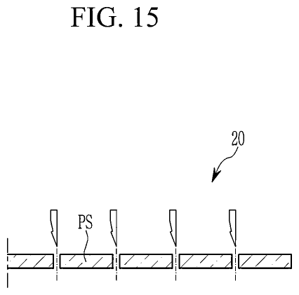

Referring to FIG. 15, finally, singulation of a plurality of semiconductor packages PS from the wafer structure 20 may be performed. As an example, the wafer structure 20 may be divided into the plurality of semiconductor packages PS, using a blade. As another example, the wafer structure 20 be divided into the plurality of semiconductor packages PS, using a laser or plasma. However, example embodiments of singulation of the plurality of semiconductor packages PS are not limited to the above examples.

While inventive concepts have been described in connection with what are presently considered to be practical example embodiments, it is to be understood by one of ordinary skill in the art that the invention is not limited to the described example embodiments. On the contrary, inventive concepts are intended to cover various modifications and equivalent arrangements included within the spirit and scope of the appended claims.

### DESCRIPTION OF SYMBOLS

10 Carrier substrate
11 First surface
12 Second surface
13 Inclined surface
14 Side surface
15 Notch groove
20 Wafer structure
50 Bonding member
100 Position detection apparatus
110 Support unit
120 Driver
130 Photosensor
140 Light source
150 Controller

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about,” “almost,” or “substantially” are used in this specification in connection with a numerical value, it is intended that the associated numerical value includes a manufacturing or operational tolerance (e.g., ±10%) around the stated numerical value. Moreover, when the words “generally,” “like” “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the 10 same or substantially the same, and/or compositionally the same or substantially the same.

What is claimed is:

1. A carrier substrate having a circular disk shape, comprising:
a first surface;
a second surface opposite to the first surface; and
an inclined surface that
extends along an edge of the first surface,
has an inclination angle from the first surface, and
is configured to reflect incident light radiated from the second surface.

2. The carrier substrate of claim 1, wherein:
the carrier substrate at least partially defines a notch groove, the notch groove having a shape of a cut at a portion of an edge portion and extending from the first surface to the second surface.

3. The carrier substrate of claim 2, wherein:
on a plane, the notch groove extends further inwards than the inclined surface.

4. The carrier substrate of claim 1, wherein
the inclined surface is inclined from the first surface toward the second surface.

5. The carrier substrate of claim 1, wherein
the inclination angle satisfies the following expression:
$$arcsin ( {n}_{a} / {n}_{s} ) \leq a < 90 ° , \qquad [ Expression ]$$
and
in the expression, a, nₐ, and nₛ are the inclination angle in degrees, the refractive index of air, and the refractive index of the carrier substrate, respectively.

6. The carrier substrate of claim 1, wherein
the light transmittance of the carrier substrate is equal to or greater than 95%.

7. A carrier substrate which has a circular disk shape and is transparent, comprising:
a first surface;
a second surface opposite to the first surface;
an inclined surface that extends along an edge of the first surface, has an inclination angle from the first surface, and is inclined toward the second surface; and
a side surface that extends from an edge of the inclined surface to an edge of the second surface,
wherein the inclination angle satisfies the following expression:
$$arcsin ( {n}_{a} / {n}_{s} ) \leq a < 90 ° , \qquad [ Expression ]$$
and
in the expression, a, nₐ, and nₛ are the inclination angle in degrees, the refractive index of air, and the refractive index of the carrier substrate, respectively.

8. The carrier substrate of claim 7, wherein:
the carrier substrate includes a glass material.

9. The carrier substrate of claim 7, wherein:
a notch groove is defined by an edge portion of the carrier substrate so as to extend along the edge portion in a thickness direction, the thickness direction perpendicular to the first surface and to the second surface, and
the notch groove has the shape of a cut defined inwardly from the side surface.

10. A method of manufacturing a semiconductor package, comprising:
preparing a carrier substrate, the carrier substrate having a circular disk shape, including an inclined surface extending along an edge, and defining a notch groove having the shape of a cut at the edge;
bonding a wafer structure onto the carrier substrate;
aligning the carrier substrate;
processing the wafer structure; and
debonding the carrier substrate,
wherein in the aligning of the carrier substrate,
a position of the notch groove is detected by radiating light onto the inclined surface such that light incident on the inclined surface is reflected thereby.

11. The method of manufacturing the semiconductor package according to claim 10, wherein:
in the preparing of the carrier substrate,
the carrier substrate is transparent and includes a first surface and a second surface, the second surface being opposite to the first surface, and an edge of the first surface is processed to form the inclined surface.

12. The method of manufacturing the semiconductor package according to claim 11, wherein:
the inclined surface is formed so as to have an inclination angle from the first surface toward the second surface, and
the inclination angle satisfies the following expression:
$$arcsin ( {n}_{a} / {n}_{s} ) \leq a < 90 ° , \qquad [ Expression ]$$
and
in the expression, a, nₐ, and nₛ are the inclination angle in degrees, the refractive index of air, and the refractive index of the carrier substrate, respectively.

13. The method of manufacturing the semiconductor package according to claim 12, wherein:
in the aligning of the carrier substrate,
while the carrier substrate is being rotated, the light is radiated from a light source, the light being radiated to the second surface and towards the inclined surface, the light source apart from the second surface and sensed by a photosensor, the photosensor apart from the first surface so as to face the light source with the carrier substrate interposed therebetween.

14. The method of manufacturing the semiconductor package according to claim 10, wherein:
in the bonding of the wafer structure,
a bonding member is interposed between the wafer structure and the carrier substrate.

15. The method of manufacturing the semiconductor package according to claim 10, wherein:
in the bonding of the wafer structure,
the wafer structure is bonded to an inner area of one surface of the carrier substrate such that the inclined surface is at least partially exposed.

16. The method of manufacturing the semiconductor package according to claim 10, further comprising:
after the bonding of the wafer structure,
grinding a surface of the wafer structure that is opposite to a surface bonded to the carrier substrate.

17. The method of manufacturing the semiconductor package according to claim 10, wherein:
in the aligning of the carrier substrate,
while the carrier substrate is being rotated, an amount of light passing through the carrier substrate and the notch is sensed to detect the position of the notch groove.

18. The method of manufacturing the semiconductor package according to claim 17, wherein:
in the aligning of the carrier substrate,
the light is radiated from a light source, the light source apart from the carrier substrate, and the amount of light is sensed by a photosensor, the photosensor located so as to face the light source with the carrier substrate interposed therebetween.

19. The method of manufacturing the semiconductor package according to claim 18, wherein:
in the aligning of the carrier substrate,
a position from which the amount of light sensed by the photosensor is greater than a reference value is detected as the position of the notch groove, and
the reference value is a maximum value of the amount of light that passes through the carrier substrate.

20. The method of manufacturing the semiconductor package according to claim 10, wherein:
in the processing of the wafer structure,
an edge portion of the wafer structure is trimmed.
